(19) United States
(12) Patent Application Publication
(10) Pub. No.: US 2020/0371167 A1
(43) Pub. Date: Nov. 26, 2020

(54) CONNECTOR INSPECTION APPARATUS AND CONNECTOR MODULE

(71) Applicant: JAPAN AVIATION ELECTRONICS INDUSTRY, LIMITED, Tokyo (JP)

(72) Inventor: Junji OOSAKA, Tokyo (JP)

(73) Assignee: JAPAN AVIATION ELECTRONICS INDUSTRY, LIMITED, Tokyo (JP)

(21) Appl. No.: 16/837,264

(22) Filed: Apr. 1, 2020

(30) Foreign Application Priority Data
May 20, 2019 (JP) 2019-094450

(51) Int. Cl. G01R 31/68; G01R 1/04; H01R 31/06; H01R 13/24

(52) U.S. Cl. CPC G01R 31/68; G01R 1/0416; H01R 2201/20; H01R 13/2471; H01R 31/065

(57) ABSTRACT

A connector inspection apparatus includes a first main body part, a terminal, and a connector module. The connector module includes a second main body part, a contact part, and a connector. The connector is a counterpart connector of a connector to be inspected. In a state in which the connector module is attached to the first main body part, the terminal and the contact part are in contact with each other and the terminal is electrically connected with a contact pin of the connector via the contact part.

### TECHNICAL FIELD

The present disclosure relates to a connector inspection apparatus and a connector module.

### BACKGROUND ART

A connector inspection apparatus used for inspecting a connector, for example, inspecting defects or characteristics of a connector is known. As prior art, International Publication No. WO2018/116568 (hereinafter referred to as Patent Literature 1) and Japanese Patent Application Laid Open No. 2004-170182 (hereinafter referred to as Patent Literature 2) can be exemplified. The connector inspection apparatuses of Patent Literature 1 and Patent Literature 2 include terminals (see the reference numeral 16 referred to in Patent Literature 1 and the reference numeral 11 referred to in Patent Literature 2) that are brought into contact with contact pins of the connector. FIG. 1 of the present specification is a copy of FIG. 8B of Patent Literature 1, and FIG. 2 of the present specification is a copy of FIG. 3 of Patent Literature 2.

A connector inspection apparatus is designed for a specific connector. For example, an arrangement of terminals of a connector inspection apparatus is determined in consideration of an arrangement of contact pins of a connector to be inspected. Accordingly, one connector inspection apparatus cannot be commonly used for connectors which have mutually different contact pin arrangements, in general. In other words, a connector inspection apparatus needs to be newly designed in accordance with change of a connector to be inspected.

Further, from the viewpoint of realizing appropriate contact with contact pins, a terminal of a connector inspection apparatus is generally a plunger coupled with a spring structure. Therefore, when an interval between contact pins of a connector to be inspected is narrow, it is difficult to appropriately design a terminal, which is a plunger coupled with a spring structure, in accordance with the narrow interval between the contact pins.

### BRIEF SUMMARY OF THE INVENTION

Based on such a technical background, a connector inspection apparatus, in which a design of a terminal is not affected by a connector to be inspected, and a connector module are provided.

The following technical matters are described simply to facilitate the understanding of the main points of the present invention, not to limit the invention claimed in the claims explicitly or implicitly and not to express the possibility of accepting such a limitation that is imposed by a person other than those who will benefit from the present invention (for example, the applicant and the right holder). The general outline of the present invention described from other perspectives can be understood from, for example, the claims of this application as originally filed at the time of application.

When a first connector which is to be inspected is manufactured, a second connector which is a counterpart of the first connector is also manufactured in general. The present invention takes advantage of this fact.

A connector inspection apparatus which is disclosed has a structure which enables a second connector, which serves as a counterpart of a first connector which is to be inspected, to be attached. Specifically, the connector inspection apparatus which is disclosed includes a first main body part, a terminal included in the first main body part, and a module to be attached to the first main body part. The module includes a second main body part and a second connector fixed on the second main body part. In a state in which the module is attached to the first main body part, conduction between the terminal and the second connector is secured.

A connector module which is disclosed corresponds to the above-mentioned module.

These and other objects, features and advantages of the present invention will become apparent from the detailed description taken in conjunction with the accompanying drawings.

### Effects of the Invention

According to the present invention, in the connector inspection apparatus, since the first main body part including the terminal is an independent component from the second main body part on which a connector is fixed, the connector serving as a counterpart of a connector to be inspected, design of the terminal is not affected by the connector to be inspected.

### BRIEF DESCRIPTION OF THE DRAWINGS

The subject matter, which is regarded as the invention, is particularly pointed out and distinctly claimed in the claims at the conclusion of the specification. The present invention itself, and manner in which it may be made or used, if any, may be better understood after a review of the following description in connection with the accompanying drawings in which:

FIG. 1 shows FIG. 8B of Patent Literature 1;

FIG. 2 shows FIG. 3 of Patent Literature 2;

FIG. 3 illustrates a connector inspection apparatus which is in a state in which a connector module is not attached;

FIG. 4 illustrates a back surface of the connector module illustrated in FIG. 3;

FIG. 5 illustrates a connector which is fixed on the connector module; and

FIG. 6 illustrates the connector inspection apparatus to which the connector module is attached.

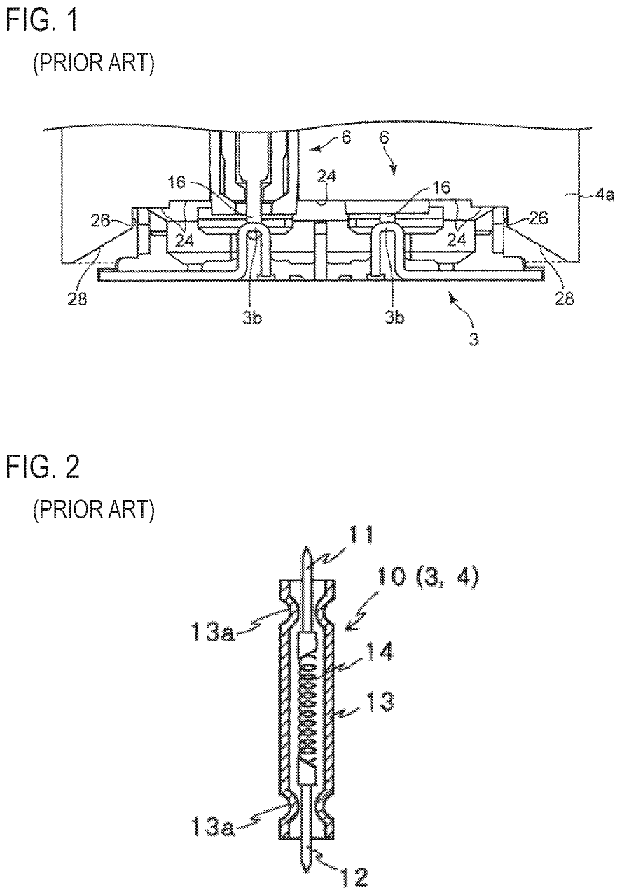

### LIST OF REFERENCE NUMERALS

With regard to reference numerals used, the following numbering is used throughout the drawings.
100: connector inspection apparatus
101: first main body part
103: terminal
105: positioning pin
200: connector module
201: second main body part
203: contact part
205: penetrating hole
250: connector
251: contact pin

### DETAILED DESCRIPTION

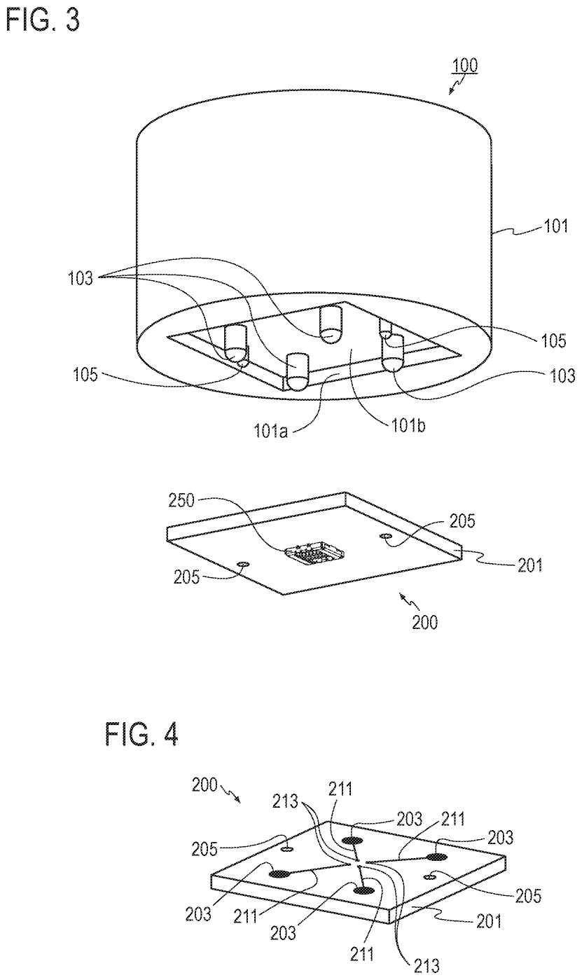

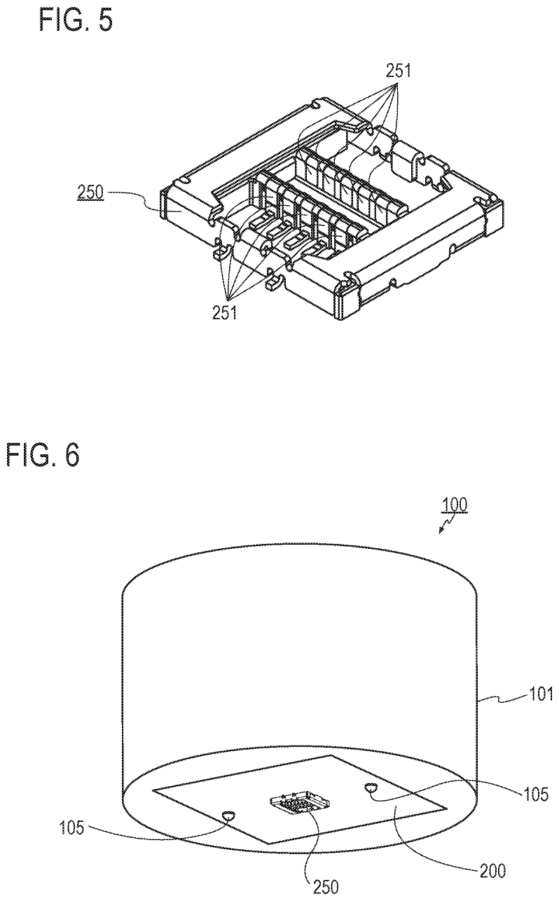

A structure of a connector inspection apparatus 100 of an embodiment and a structure of a connector module 200 that can be a component of the connector inspection apparatus 100 are described with reference to FIGS. 3 to 6.

The connector inspection apparatus 100 includes a first main body part 101, L pieces of conductive terminals 103 included in the first main body part 101, and a connector module 200 which is attachable to the first main body part 101. L denotes a predetermined integer which is 1 or greater. In the present embodiment, L pieces of terminals 103 each having a rod shape are protruded from a bottom surface 101b of a recessed portion 101a which is formed on a lower surface of the first main body part 101 having a column shape. Further, two positioning pins 105 are protruded from the bottom surface 101b in the present embodiment.

<First Main Body Part>

The first main body part 101 is a device that functions as a connector inspection apparatus for inspecting a connector to be inspected in a state in which the connector module 200 is attached to the first main body part 101. Note that the denial of this proposition is not always true. In other words, the first main body part 101 is not always a “device that does not function as a connector inspection apparatus in a state in which the connector module 200 is not attached to the first main body part 101”.

That is, the first main body part 101 may be the connector inspection apparatus itself of prior art, for example. In this case, the terminals 103 included in the first main body part 101 correspond to the above-described terminals included in the connector inspection apparatus of prior art. As described above, in prior art, the terminals are parts to be brought into contact with contact pins of a connector to be inspected. However, the terminals 103 included in the first main body part 101 are not directly brought into contact with contact pins of a connector to be inspected (not shown), as described later. Note that, in the present embodiment, the first main body part 101 is not singly used for inspection of a connector to be inspected even though the first main body part 101 is the connector inspection apparatus itself of prior art. The first main body part 101 is not limited to the connector inspection apparatus of prior art and may be a device designed in consideration of the structure of the connector module 200.

In the present embodiment, the first main body part 101 is the connector inspection apparatus of prior art and each of the L pieces of terminals 103 is a plunger. Since a spring structure to which a plunger is coupled and the structure of the connector inspection apparatus of prior art incorporating a combination of the plunger and the spring structure are well known, detailed description thereof is to be omitted. The structure of the first main body part 101 is not limited except that the first main body part 101 is structured to be capable of securely holding the connector module 200.

<Connector Module>

The connector module 200 includes a second main body part 201, M pieces of contact parts 203, and a connector 250. M denotes a predetermined integer which is 1 or greater.

The second main body part 201 is structured to be able to be fixed to a tangible object other than the connector module 200, that is, to the first main body part 101. In the present embodiment, the second main body part 201 is a board having a rectangular flat plate shape. The second main body part 201 includes two penetrating holes 205. The connector 250 is positioned on one surface of the second main body part 201.

The connector 250 is fixed on the second main body part 201 and includes N pieces of contact pins 251. N denotes a predetermined integer which is 1 or greater. The connector 250 is a counterpart connector of a connector to be inspected (not shown). In the present embodiment, the connector 250 is a plug connector and a connector to be inspected is a receptacle connector which can be fitted with the connector 250.

For the above-mentioned L, M, and N, M≤N and M≤L hold. M denotes a total number of conductive paths which can be used in inspection. The condition of M≤N is based on the fact that all contact pins are not necessarily used in inspection. The condition of M≤L represents that a connector inspection apparatus of prior art satisfying M≤L can be used as the first main body part 101. In the present embodiment, L=4, M=4, and N=10 hold.

In the present embodiment, the M pieces of contact parts 203 are positioned on the other surface of the second main body part 201. Each of the M pieces of contact parts 203 is a portion of one contact pin 251 or a tangible object other than the contact pin 251.

When the contact part 203 is a tangible object other than the contact pin 251, the tangible object is a terminal having a thin flat plate shape, for example (see FIG. 4). In this case, M pieces of contact pins 251 which can be used in inspection are electrically connected with M pieces of contact parts 203 respectively. As a specific example, end portions of the M pieces of contact pins 251 (here, each of these end portions is not an end portion which is brought into contact with a contact pin of a connector to be inspected, in two end portions of a contact pin 251) are connected with the M pieces of contact parts 203, which are formed or disposed on the other surface of the second main body part 201, via through holes 213 formed in the second main body part 201 and conductive lines 211 formed on the other surface of the second main body part 201. The through hole 213 is formed as needed.

When the contact part 203 is a portion of the contact pin 251 (not shown), the entire length of each of the M pieces of contact pins 251 which can be used in inspection is longer than that of the rest N-M pieces of contact pins. End portions of these M pieces of contact pins 251 (here, each of these end portions is not an end portion which is brought into contact with a contact pin of a connector to be inspected, in two end portions of a contact pin 251) are the M pieces of contact parts 203. As a specific example, the M pieces of contact pins 251 protruded from the other surface of the second main body part 201 are bent and the end portions of the M pieces of contact pins 251 are positioned on the other surface of the second main body part 201 or positioned near the other surface.

<Connector Inspection Apparatus>

The connector module 200 is attached to the recessed portion 101a formed on the lower surface of the first main body part 101 in the present embodiment. Positioning of the connector module 200 is realized by inserting the two positioning pins 105 into the two penetrating holes 205 respectively.

The attachment method is not limited and the connector module 200 may be attached to the first main body part 101 with adhesive, for example. In this case, the structure by which the first main body part 101 can hold the connector module 200 is the bottom surface 101b of the recessed portion 101a to which adhesive is applied, and the structure which enables the second main body part 201 to be fixed to the first main body part 101 is the other surface of the second main body part 201 to which adhesive is applied. Further, the connector module 200 may be attached to the first main body part 101 with screws, for example. In this case, the structure by which the first main body part 101 can hold the connector module 200 is screw holes (not shown) formed on the bottom surface 101b of the recessed portion 101a, and the structure which enables the second main body part 201 to be fixed to the first main body part 101 is screw holes (not shown) formed on the second main body part 201. Further, the connector module 200 may be attached to the first main body part 101 with engaging parts and engaged parts, for example. In this case, the structure by which the first main body part 101 can hold the connector module 200 is engaged parts which are recessed (not shown), and the structure which enables the second main body part 201 to be fixed to the first main body part 101 is engaging parts which are protruded (not shown).

In the state in which the connector module 200 is attached to the first main body part 101, the M pieces of contact parts 203 and the M pieces of terminals 103 which can be used in inspection are directly in contact with each other respectively. That is, in the state in which the connector module 200 is attached to the first main body part 101, the M pieces of contact parts 203 and the M pieces of terminals 103 are not soldered to each other. As described above, in the state in which the connector module 200 is attached to the first main body part 101, the M pieces of terminals 103 which can be used in inspection are electrically connected with the M pieces of contact pins 251 respectively via the M pieces of contact parts 203, in the present embodiment.

As is apparent from the present embodiment, in the connector inspection apparatus 100, the terminals 103 are not brought into contact with a connector to be inspected. Further, in the connector inspection apparatus 100, the first main body part 101 including the terminals 103 is an independent component from the second main body part 201 on which a counterpart connector is fixed, the counterpart connector being brought into contact with a connector to be inspected. Accordingly, design of the terminals 103 is not affected by a connector to be inspected. That is, there is no need to change design of the terminals 103 in accordance with an interval or an arrangement of contact pins of a connector to be inspected. Further, in the structure in which the connector module 200 is detachable from the first main body part 101, a user only has to change the connector module 200 which is interposed between the terminals 103 and a connector to be inspected in accordance with change of a connector to be inspected. Since electrical conduction between the contact parts 203 and the contact pins 251 can be attained by existing techniques such as a printed circuit board technique and molding of the contact pins 251, the connector module 200 is easily manufactured.

When a connector to be inspected is a high frequency connector which is used for transmitting a high frequency signal, there is no disturbance of passage characteristics caused by solder, according to the present embodiment. Further, when a connector to be inspected is a high frequency connector, it is preferable that an electrical distance between the i-th contact point among M pieces of contact points and the i-th contact part 203 among M pieces of contact parts 203 is equal to an electrical distance between the j-th contact point among M pieces of contact points and the j-th contact part 203 among M pieces of contact parts 203. Here, the contact point is one portion of the contact pin 251 and is a portion brought into contact with a connector to be inspected. The k-th contact point belongs to the k-th contact pin 251 and the k-th contact part 203 is brought into contact with the k-th contact pin 251. Further, i∈{1, 2, . . . , M}, j∈{1, 2, . . . , M}, and k∈{1, 2, . . . , M} hold. When the contact part 203 is a terminal as described above, wiring between the M pieces of contact points and the M pieces of contact parts 203 is equal-delay wiring or equal-length wiring. When the contact part 203 is a portion of the contact pin 251, an electrical distance between the i-th contact point among M pieces of contact points and the i-th contact part 203 among M pieces of contact parts 203 is equal to an electrical distance between the j-th contact point among M pieces of contact points and the j-th contact part 203 among M pieces of contact parts 203, in a similar manner. However, the k-th contact point and the k-th contact part 203 belong to the k-th contact pin 251.

Further, the connector inspection apparatus 100 may include an elastic structure for enhancing contact force between the M pieces of terminals 103 which can be used in inspection and the M pieces of contact parts 203. In the present embodiment, the elastic structure is a spring structure to which the terminals 103, which are plungers, are coupled. When the contact part 203 is a portion of the contact pin 251, the elastic structure may be the contact pin 251, which is bent, itself. In other words, the contact pin 251 which is bent functions as a leaf spring in this case. Alternatively, the contact part 203 may be a tangible object having the elastic structure, for example, a device including a plunger and a spring structure coupled to the plunger (referred to by those skilled in the art as a pogo pin, a spring pin, a spring probe, and the like).

The connector 250 is not limited to a board-to-board connector which is illustrated. Further, there is no limit in a shape and application of the connector 250. The shape of the second main body part 201 is not limited either, and accordingly, the shape of the second main body part 201 may be arbitrarily determined depending on the shape of the first main body part 101 and a positional relation between the terminals 103 and a connector to be inspected in inspection, for example. Thus, there is no limit in a position of the connector 250 and positions of the contact parts 203 on the second main body part 201.

Addendum

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims.

Moreover, the use of the terms “first”, “second”, “i-th”, etc., if any, do not denote any order or importance, but rather the terms “first”, “second”, “i-th”, etc. are used to distinguish one element from another. The term “first” does not necessarily mean “coming before all others in order”. The terminology used herein is for the purpose of describing particular embodiments only and is not intended to limit the invention in any way. As used herein, the singular forms “a”, “an” and “the” are intended to include the plural forms as well, unless the context clearly indicates otherwise. It will be further understood that the terms “comprise”, “comprises”, and/or “comprising,” when used in this specification and/or the appended claims, specify the presence of stated features, steps, operations, elements, and/or components, but do not preclude the presence or addition of one or more other features, steps, operations, elements, components, and/or groups thereof. The same goes for “include”, “includes”, and/or “including”. The term “and/or”, if any, includes any and all combinations of one or more of the associated listed items. In the claims and the specification, unless otherwise noted, “connect”, “join”, “couple”, “interlock”, or synonyms therefor and all the word forms thereof, if any, do not necessarily deny the presence of one or more intermediate elements between two elements, for instance, two elements “connected” or “joined” to each other or “interlocked” with each other. Connection between elements, if required, may be physical connection, electrical connection, or a combination thereof.

Unless otherwise defined, all terms (including technical and scientific terms) used herein have the same meaning as commonly understood by those skilled in the art to which the invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

In describing the invention, it will be understood that a number of techniques and steps are disclosed. Each of these has individual benefit and each can also be used in conjunction with one or more, or in some cases all, of the other disclosed techniques. Accordingly, for the sake of clarity, this description will refrain from repeating every possible combination of the individual techniques or steps in an unnecessary fashion. Nevertheless, the specification and claims should be read with the understanding that such combinations are entirely within the scope of the invention and the claims.

The corresponding structures, materials, acts, and equivalents of all means or step plus function elements in the claims below, if any, are intended to include any structure, material, or act for performing the function in combination with other claimed elements as specifically claimed.

The foregoing description of the embodiments of the invention has been presented for the purpose of illustration and description. It is not intended to be exhaustive and to limit the invention to the precise form disclosed. Modifications or variations are possible in light of the above teaching. The embodiments were chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. An apparatus for inspection of a connector comprising:
a first main body part;
one or more terminals included in the first main body part; and
a module to be attached to the first main body part,
the module including:
a second main body part;
one or more contact parts; and
a connector being a counterpart of the connector to be inspected, being fixed on the second main body part, and including one or more contact pins, and
the one or more terminals and the one or more contact parts being in contact with each other and the one or more terminals being electrically connected with the one or more contact pins via the one or more contact parts, with the module attached to the first main body part.

2. The apparatus according to claim 1, wherein each of the one or more contact parts is a portion of a corresponding one of the one or more contact pins.

3. The apparatus according to claim 1, wherein
the one or more contact parts each are a tangible object other than the one or more contact pins, and
the one or more contact pins are electrically connected with the one or more contact parts.

4. The apparatus according to claim 1, wherein in the state in which the module is attached to the first main body part, the one or more terminals and the one or more contact parts are not soldered to each other.

5. The apparatus according to claim 2, wherein in the state in which the module is attached to the first main body part, the one or more terminals and the one or more contact parts are not soldered to each other.

6. The apparatus according to claim 3, wherein in the state in which the module is attached to the first main body part, the one or more terminals and the one or more contact parts are not soldered to each other.

7. The apparatus according to claim 1, further comprising:
an elastic structure that enhances contact force between the one or more terminals and the one or more contact parts.

8. The apparatus according to claim 2, further comprising:
an elastic structure that enhances contact force between the one or more terminals and the one or more contact parts.

9. The apparatus according to claim 3, further comprising:
an elastic structure that enhances contact force between the one or more terminals and the one or more contact parts.

10. The apparatus according to claim 4, further comprising:
an elastic structure that enhances contact force between the one or more terminals and the one or more contact parts.

11. The apparatus according to claim 5, further comprising:
an elastic structure that enhances contact force between the one or more terminals and the one or more contact parts.

12. The apparatus according to claim 6, further comprising:
an elastic structure that enhances contact force between the one or more terminals and the one or more contact parts.

13. The apparatus according to claim 1, wherein
the second main body part has a flat plate shape,
the counterpart of the connector to be inspected is positioned on one surface of the second main body part, and
the one or more contact parts are positioned on the other surface of the second main body part.

14. The apparatus according to claim 2, wherein
the second main body part has a flat plate shape,
the counterpart of the connector to be inspected is positioned on one surface of the second main body part, and
the one or more contact parts are positioned on the other surface of the second main body part.

15. The apparatus according to claim 3, wherein
the second main body part has a flat plate shape,
the counterpart of the connector to be inspected is positioned on one surface of the second main body part, and
the one or more contact parts are positioned on the other surface of the second main body part.

16. The apparatus according to claim 4, wherein
the second main body part has a flat plate shape,
the counterpart of the connector to be inspected is positioned on one surface of the second main body part, and
the one or more contact parts are positioned on the other surface of the second main body part.

17. The apparatus according to claim 5, wherein
the second main body part has a flat plate shape,
the counterpart of the connector to be inspected is positioned on one surface of the second main body part, and
the one or more contact parts are positioned on the other surface of the second main body part.

18. The apparatus according to claim 6, wherein
the second main body part has a flat plate shape,
the counterpart of the connector to be inspected is positioned on one surface of the second main body part, and
the one or more contact parts are positioned on the other surface of the second main body part.

19. The apparatus according to claim 7, wherein
the second main body part has a flat plate shape,
the counterpart of the connector to be inspected is positioned on one surface of the second main body part, and
the one or more contact parts are positioned on the other surface of the second main body part.

20. The apparatus according to claim 8, wherein
the second main body part has a flat plate shape,
the counterpart of the connector to be inspected is positioned on one surface of the second main body part, and
the one or more contact parts are positioned on the other surface of the second main body part.

21. The apparatus according to claim 9, wherein
the second main body part has a flat plate shape,
the counterpart of the connector to be inspected is positioned on one surface of the second main body part, and
the one or more contact parts are positioned on the other surface of the second main body part.

22. The apparatus according to claim 10, wherein
the second main body part has a flat plate shape,
the counterpart of the connector to be inspected is positioned on one surface of the second main body part, and
the one or more contact parts are positioned on the other surface of the second main body part.

23. The apparatus according to claim 11, wherein
the second main body part has a flat plate shape,
the counterpart of the connector to be inspected is positioned on one surface of the second main body part, and
the one or more contact parts are positioned on the other surface of the second main body part.

24. The apparatus according to claim 12, wherein
the second main body part has a flat plate shape,
the counterpart of the connector to be inspected is positioned on one surface of the second main body part, and
the one or more contact parts are positioned on the other surface of the second main body part.

25. The apparatus according to claim 1, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

26. The apparatus according to claim 2, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

27. The apparatus according to claim 3, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

28. The apparatus according to claim 4, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

29. The apparatus according to claim 5, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

30. The apparatus according to claim 6, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

31. The apparatus according to claim 7, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

32. The apparatus according to claim 8, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

33. The apparatus according to claim 9, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

34. The apparatus according to claim 10, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

35. The apparatus according to claim 11, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

36. The apparatus according to claim 12, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

37. The apparatus according to claim 13, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

38. The apparatus according to claim 14, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

39. The apparatus according to claim 15, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

40. The apparatus according to claim 16, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

41. The apparatus according to claim 17, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

42. The apparatus according to claim 18, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

43. The apparatus according to claim 19, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

44. The apparatus according to claim 20, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

45. The apparatus according to claim 21, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

46. The apparatus according to claim 22, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

47. The apparatus according to claim 23, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

48. The apparatus according to claim 24, wherein
the one or more contact parts include two or more contact parts,
the one or more contact pins include two or more contact pins, and
electrical distances between portions of the two or more contact pins, the portions being brought into contact with the connector to be inspected, and the two or more contact parts are mutually equal.

49. A connector module comprising:
a main body part having a structure enabling the connector module to be fixed to a tangible object other than the connector module;
one or more contact parts; and
a connector being fixed on the main body part and including one or more contact pins,
each of the one or more contact parts being a portion of a corresponding one of the one or more contact pins, or the one or more contact parts each are a tangible object other than the one or more contact pins and the one or more contact pins being electrically connected with the one or more contact parts.

50. The connector module according to claim 49, wherein the tangible object is a device functioning as an apparatus that inspects a connector serving as a counterpart of the connector in a state in which the connector module is fixed thereto.

51. The connector module according to claim 49, wherein
the one or more contact parts include two or more contact parts,
the one or more contact pins include two or more contact pins, and
electrical distances between predetermined portions of the two or more contact pins and the two or more contact parts are mutually equal.

52. The connector module according to claim 50, wherein
the one or more contact parts include two or more contact parts,
the one or more contact pins include two or more contact pins, and
electrical distances between predetermined portions of the two or more contact pins and the two or more contact parts are mutually equal.
